(19) United States
(12) Patent Application Publication
(10) Pub. No.: US 2007/0099407 A1
(43) Pub. Date: May 3, 2007

(54) Method for fabricating a transistor using a low temperature spike anneal

(76) Inventors: Jiong-Ping Lu, Richardson, TX (US); Shaofeng Yu, Plano, TX (US)

Correspondence Address: TEXAS INSTRUMENTS INCORPORATED, P O BOX 655474, M/S 3999, DALLAS, TX, 75265, US

(21) Appl. No.: 11/264,856

(22) Filed: Nov. 1, 2005

(51) Int. Cl. H01L 21/4763

(52) U.S. Cl. 438/592; 438/300

(57) ABSTRACT

A method for making a transistor 20 that includes performing a low temperature spike anneal 314. The method also includes performing a silicide anneal 318 to fully silicide the gate electrode 90 of the transistor 20. A blocking layer 120 protects the source and drain regions 60 of the transistor 20 during the processes of low temperature spike anneal 3.14 and silicide anneal 318.

### BACKGROUND OF THE INVENTION

This invention relates to the fabrication of a semiconductor transistor using a low temperature spike anneal process.

### BRIEF DESCRIPTION OF THE DRAWINGS

FIG. 1 is a cross-sectional view of a semiconductor structure in accordance with the present invention.

FIGS. 2A-2G are cross-sectional diagrams of a process for forming a transistor in accordance with the invention.

FIG. 3 is a flow chart illustrating the process flow of the invention.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

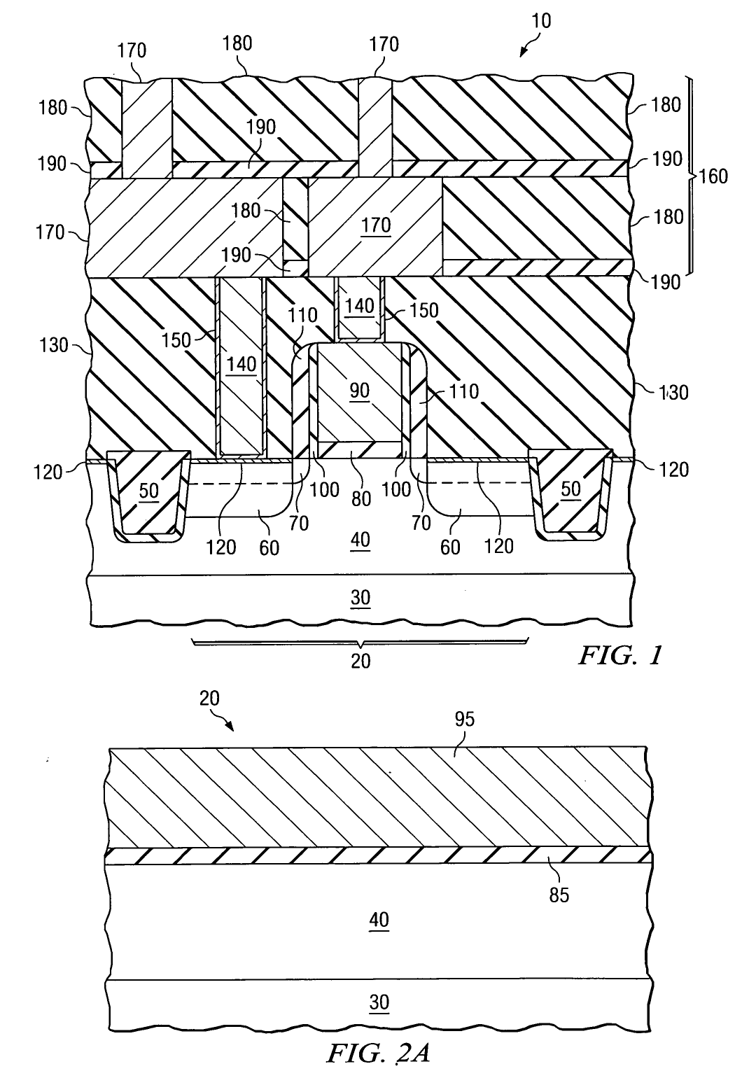

Referring to the drawings, FIG. 1 is a cross-sectional view of a semiconductor wafer 10 in accordance with the present invention. In the example application a CMOS transistor 20 is formed within a semiconductor substrate 30 having an n-well or p-well region 40. The remainder of the semiconductor wafer 10 may contain any combination of active or passive devices (not shown) such as additional CMOS, BiCMOS and bipolar junction transistors, capacitors, optoelectronic devices, inductors, resistors, and diodes.

The CMOS transistor 20 is electrically insulated from other active devices by shallow trench isolation structures 50 formed within the semiconductor substrate 30, 40; however, any conventional isolation structure may be used such as field oxide regions or implanted isolation regions. The semiconductor substrate 30 is any semiconducting material that is doped with n-type and p-type dopants; however it may be an amorphous silicon substrate or a substrate that is fabricated by forming an epitaxial silicon layer on a single-crystal substrate.

Transistors, such as CMOS transistor 20, are generally comprised of a gate, a source, and a drain. More specifically, as shown in FIG. 1, the active portion of the transistors are comprised of source/drain regions 60, source/drain extension regions 70, and a gate stack that is comprised of a gate dielectric 80 and a gate electrode 90. In accordance with the invention, the gate electrode 90 is fully silicided (“FUSI”). The CMOS transistor may be either a p-channel MOS transistor (“PMOS”) or an n-channel MOS transistor (“NMOS”).

In the example application shown in FIG. 1, the transistor 20 is a PMOS transistor. Therefore it is formed within an n-well region 40 of the semiconductor substrate 30. In addition, the deep source and drain regions 60 and the source and drain extension regions 70 have p-type dopants such as boron. The source/drain regions 60 are usually heavily doped. However, the source/drain extension regions 70 may be lightly doped (“LDD”), medium doped (“MDD”), or highly doped (“HDD”). The PMOS gate stack is created from the p-type doped polysilicon FUSI gate electrode 90 and the oxide gate dielectric 80.

It is within the scope of the invention for transistor 20 to be an NMOS transistor. With this alternative embodiment, each of the dopant types described herein would be reversed. For example, if the transistor was an NMOS transistor then it would be formed within a p-well region of the semiconductor substrate. In addition, the deep source and drain regions and the source and drain extension regions would have n-type dopants such as arsenic, phosphorous, antimony, or a combination of n-type dopants. The sources/drain regions of an NMOS transistor are usually heavily doped. However, the source/drain extension regions could be LDD, MDD, or HDD. An NMOS gate stack is created from an n-type doped polysilicon FUSI gate electrode and an oxide gate dielectric. For clarity, this alternative transistor structure will not be discussed in detail since it is well known in the industry how to reverse the dopant types to create an NMOS transistor that is the counterpart to the PMOS transistor described herein.

An offset structure comprising extension sidewalls 100 and spacer sidewalls 110 are used during fabrication to enable the proper placement of the source/drain extension regions 70 and the sources/drain regions 60, respectively. More specifically, the extension regions 70 are usually formed using the gate stack 80, 90 and extension sidewalls 100 as a mask. In addition, the sources/drain regions 60 are usually formed with the gate stack and spacer sidewalls 110 as a mask.

The top portion of the extension sidewalls 100 and the spacer sidewalls 110 are at the same level as—or slightly above or below—the top surface of the FUSI gate electrode 90. In addition, the sources/drain regions 60—as well as other areas of exposed silicon substrate—have a layer of silicide 120 that is formed within the top surface during the fabrication process. The silicide layer 120 is preferably CoSi₂; however, it is within the scope of the invention to fabricate the silicide 120 with other metals (such as nickel, platinum, titanium, tantalum, molybdenum, tungsten, or alloys of these metals). Moreover, the silicide layer 120 that is formed on the top surface of the sources/drain regions 60 may be a self-aligned silicide (i.e. a “salicide”)

In accordance with the invention, the gate electrode 90 is fully silicided during the semiconductor fabrication process. The FUSI gate electrode 90 has the advantages of low resistance and no poly depletion in comparison to polycrystalline silicon (i.e. “polysilicon” or “poly”) gate electrodes. In addition, the fully silicided gate electrode 90 facilitates the reduction of the contact resistance between the transistor 20 and the electrical contacts 140/150. The FUSI gate electrode is preferably comprised of NiSi; however, silicides of other nickel alloys may be used, such as NiAl suicides or NiPt silicides. With the use of the low temperature spike anneal process described below; the metal density of the FUSI gate electrodes is uniform throughout the semiconductor wafer—regardless of whether the width of the FUSI gate electrode 90 is wide or narrow. In addition, the use of the low temperature spike anneal process will help prevent against punch-through failures caused by the excess metal located at the interface between the FUSI gate electrode 90 and the gate dielectric 80 that is often present when other processes are used. Therefore, the use of the low temperature spike anneal process improves device reliability and reduces variations in threshold voltages between transistors having gate electrodes of different line widths and doping conditions.

Referring again to FIG. 1, a layer of dielectric insulation 130 surrounds the transistor 20 (and also surrounds the other devices on the semiconductor wafer). The composition of dielectric insulation 130 may be any suitable material such as SiO₂ or organosilicate glass (“OSG”). The dielectric material 130 electrically insulates the metal contacts 140 that electrically connects the CMOS transistor 20 that is shown in FIG. 1 to other active or passive devices (not shown) that are located throughout the semiconductor wafer 10. An optional dielectric liner (not shown) may be formed over the semiconductor wafer before the placement of the dielectric insulation layer 130. If used, the dielectric liner may be any suitable material such as silicon nitride.

In this example application, the contacts 140 are comprised of W; however, any suitable material (such as Cu, Ti, Al, or an alloy) may be used. In addition, an optional liner material 150 such as Ti, TiN, or Ta (or any combination or layer stack thereof) may be used to reduce the contact resistance at the interface between the liners 150 and the silicided gate electrode 90 and sources/drain regions 60.

Subsequent fabrication will create the “back-end” portion 160 of the integrated circuit. The back-end 160 is generally comprised of one or more interconnect layers (and possibly via layers) containing metal interconnects 170 that properly route electrical signals and power though out the completed integrated circuit. The metal interconnects 170 may contain any suitable metal such as Cu. In addition, the metal interconnects 170 are electrically insulated by dielectric material 180, which may be any insulative material such as fluorinated silica glass (“FSG”) or OSG. Moreover, a thin dielectric layer 190 may be formed between the areas of dielectric material 180 of each interconnect layer. If used, the thin dielectric layer 190 may be comprised of any suitable material, such as SiC, SiCN, SiCO, or Si₃N₄. The very top portion of the back-end 160 (not shown) contains bond pads to connect the completed integrated circuit to the device package. In addition, the top portion of the back-end 160 often contains an overcoat layer to seal the integrated circuit.

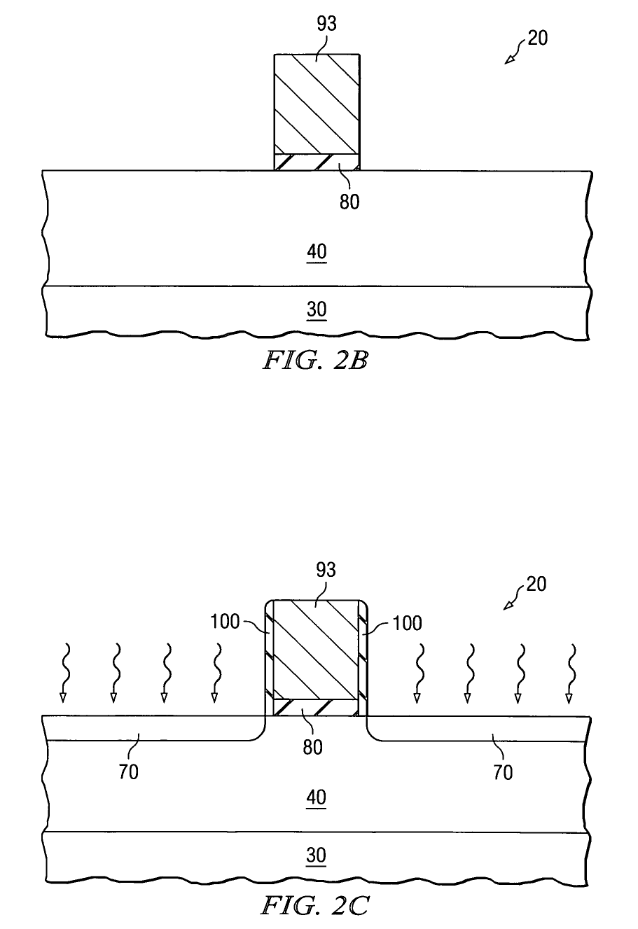

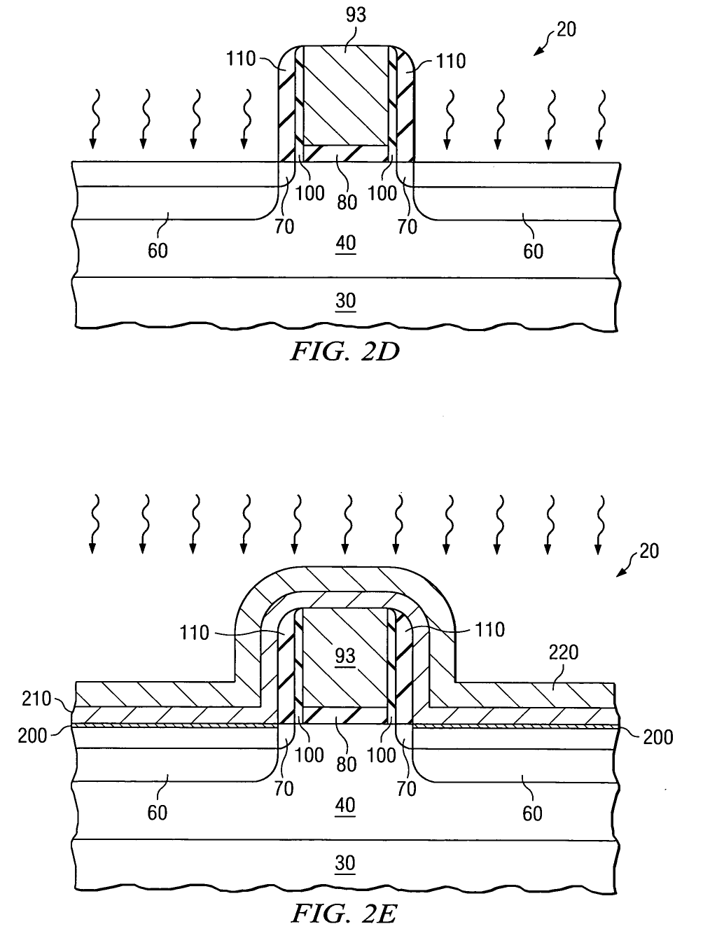

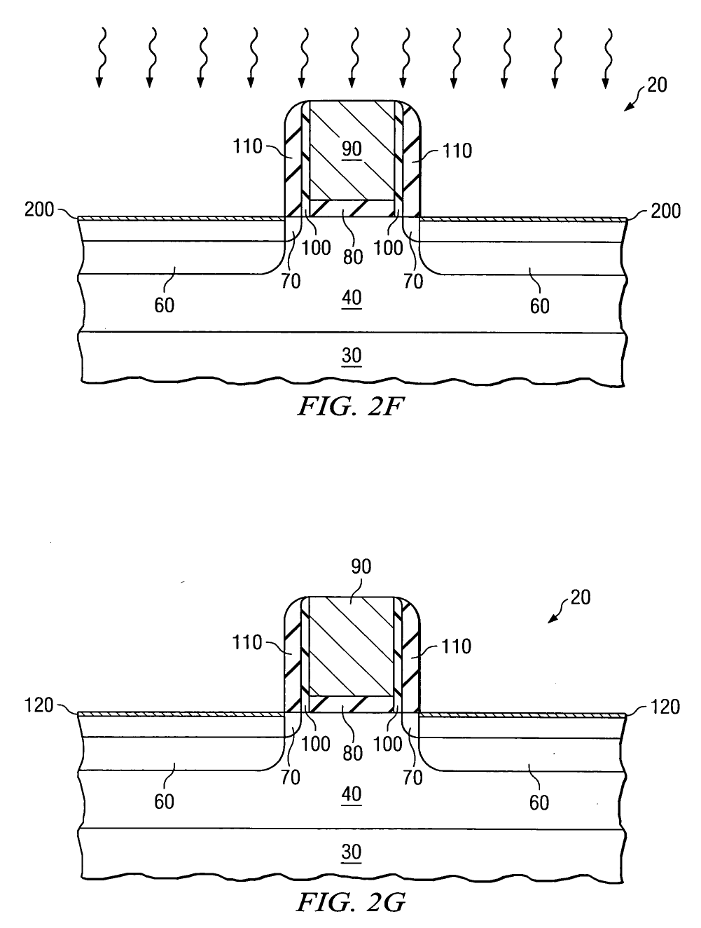

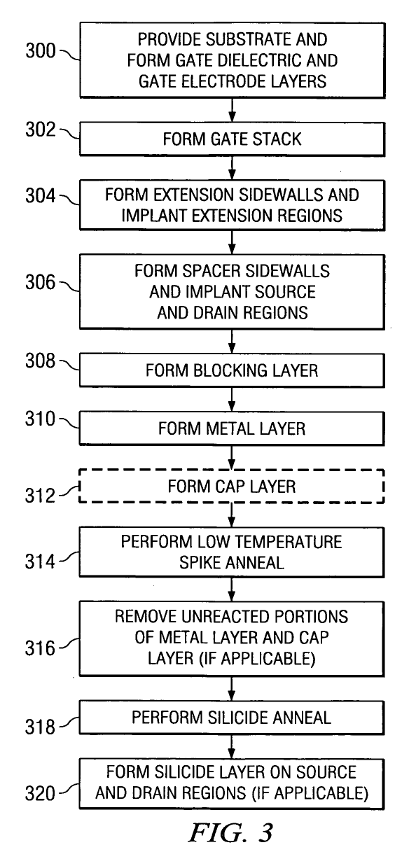

Referring again to the drawings, FIGS. 2A-2G are cross-sectional views of a partially fabricated semiconductor wafer 10 illustrating a process for forming an example PMOS transistor 20 in accordance with the present invention. Those skilled in the art of semiconductor fabrication will easily understand how to modify this process to manufacture other types of transistors (such as an NMOS transistor) in accordance with this invention. FIG. 3 is a corresponding flow chart illustrating the process flow of the invention.

FIG. 2A is a cross-sectional view of a transistor structure 20 after the formation of the gate dielectric layer 85 and the gate electrode layer 95 on the top surface of a semiconductor substrate 30 (step 300). In the example application, the semiconductor substrate 30 is a single-crystalline silicon substrate; however any suitable material such as germanium or gallium arsenide may be used. The example PMOS transistor 20 is formed within an n-well region 40 of the semiconductor substrate 30.

The gate dielectric layer 85 and the gate electrode layer 95 are formed using well-known manufacturing techniques. The first layer formed over the surface of the semiconductor substrate 30 is a gate dielectric layer 85. As an example, the gate dielectric layer 85 is silicon dioxide formed with a thermal oxidation process. However, the gate dielectric layer 85 may be any suitable material, such as nitrided silicon oxide, silicon nitride, or a high-k gate dielectric material, and may be formed using any one of a variety of processes such as an oxidation process, thermal nitridation, plasma nitridation, physical vapor deposition (“PVD”), or chemical vapor deposition (“CVD”).

A gate electrode layer 95 is then formed on the surface of the gate dielectric layer 85. The gate electrode layer 95 is comprised of polycrystalline silicon in the example application. However, it is within the scope of the invention to use other materials such as an amorphous silicon, a silicon alloy (e.g. SiGe), or other suitable materials. The gate electrode layer 95 may also be formed using any process technique such as CVD or PVD.

After a standard pattern and etch process, a gate stack having a gate dielectric 80 and a gate electrode 93 will be formed from the gate oxide layer 85 and the gate polysilicon layer 95, respectively (step 302). The gate stack, shown in FIG. 2B, may be created through a variety of processes. For example, the gate stack may be created by forming a layer of standard photoresist over the semiconductor wafer, patterning the photoresist, and then using the patterned photoresist to properly etch the gate oxide layer 85 and the gate polysilicon layer 95. This gate stack may be etched using any suitable etch process, such as an anisotropic etch using plasma or reactive ions.

The next step in the fabrication of the PMOS transistor 20 is the formation of the extension regions 70 using the extension sidewalls 100 as a template (step 304). As shown in FIG. 2C, extension sidewalls 100 are formed on the outer side surfaces of the gate stack using any standard processes and materials. The extension sidewalls 100 may be formed from a single material or may be formed from more than one layer of materials. For example, the extension sidewalls 100 may be comprised of an oxide, oxi-nitride, silicon dioxide, nitride, or any other dielectric material or layers of dielectric materials. The material layers for the extension sidewalls 100 may be formed with any suitable process, such as thermal oxidation, or deposition by ALD, CVD, or PVD. It is to be noted that the height of the extension sidewalls 100 are preferably at, or slightly above, the top of the gate electrode 93. However, the extension sidewalls 100 can also be slightly lower than the gate electrode—depending on the integration scheme used. For example, if an anisotropic etch process is used to shape the material layer or layers into the extension sidewalls 100, then the highest point of the extension sidewalls 100 will probably be slightly below the top surface of the gate electrode 93.

The gate stack and the extension sidewalls 100 are now used as a template to facilitate the proper doping of the extension regions 70. However, it is within the scope of the invention to form the extension regions 70 during a later step in the manufacturing process.

The extension regions 70 are formed near the top surface of the semiconductor substrate 30 using any standard process. For example, the extension regions 70 may be formed by low-energy ion implantation, gas phase diffusion, or solid phase diffusion. The dopants used to create the extension regions 70 for a PMOS transistor 20 are p-type (i.e. boron). The dopants used to create the extension regions for an NMOS transistor are n-type (i.e. phosphorous or arsenic). However, other dopants or combinations of dopants may be used.

In the example application shown in FIG. 2C, the extension sidewalls 100 are used to direct the dopant implantation to the proper location 70 within the semiconductor substrate 30. Due to lateral straggling of the implanted species, the extension regions 70 usually initiate from points in the semiconductor substrate 30 that are slightly inside the outer corner of the extension sidewalls 100.

At some point after the implantation of the extension regions 70, the extension regions 70 are activated by an anneal process (performed now or later) to form activated source and drain extension regions 70. This anneal step may be performed with any suitable process such as rapid thermal anneal (“RTA”). The annealing process will likely cause a lateral migration of each extension region toward the opposing extension region (not shown).

Referring to FIG. 2D, spacer sidewalls 110 are now formed proximate to the extension sidewalls 100 (step 306). The spacer sidewalls 110 may be formed using any standard process and materials. In addition the spacer sidewalls 110 may be formed from a single material or from two or more layers of materials. For example, the spacer sidewalls 110 may be comprised of a cap oxide and a silicon nitride layer that are formed with a CVD process and subsequently anisotropically etched (preferably using standard anisotropic plasma etch processes). However, it is within the scope of the invention to use more layers (i.e. a spacer oxide layer, a silicon layer, and a final oxide layer) or less layers (i.e. just a silicon oxide layer or a silicon nitride layer) to create the spacer sidewalls 110. It is to be noted that the semiconductor wafer 10 is usually subjected to a standard post-etch cleaning process after the formation of the spacer sidewalls 110. It is also to be noted that the height of the extension sidewalls 100 and the spacer sidewalls 110 are preferably at, or slightly above, the top of the gate electrode 93. However, the extension sidewalls 100 and the spacer sidewalls 110 can also be slightly lower than the gate electrode—depending on the integration scheme used.

Now the gate stack 80, 93 the extension sidewalls 100, and the spacer sidewalls 110 are used as a template for the implantation of dopants into the source/drain regions 60 (step 306). However, it is within the scope of the invention to form the source/drain regions 60 at a subsequent point in the manufacturing process.

The source/drain regions 60 may be formed through any one of a variety of processes, such as deep ion implantation or deep diffusion. The dopants used to create the source/drain regions 60 for a PMOS transistor 20 are typically boron; however, other dopants or combinations for dopants may be used. The dopants used to create the source/drain regions for an NMOS transistor are typically phosphorous or arsenic; however, other dopants or combinations for dopants may be used. Moreover, the dopant implantations may be preceded by a pre-amorphization implantation of electrically inactive ions, such as Si and Ge, forming shallow junctions by reducing dopant ion channeling.

The implantation of the dopants is self-aligned with respect to the outer edges of the spacer sidewalls 110. However, it is to be noted that due to lateral straggling of the implanted species, the source/drain regions 60 usually initiate slightly inside the outer corner of the spacer sidewalls 110 (not shown).

In the example application, the source/drain regions 60 are activated by a second anneal step to create activated sources/drain regions 60. (However, the extension region anneal and the source/drain region anneal may be combined and performed at this point in the fabrication process.) This anneal step acts to repair the damage to the semiconductor wafer and to activate the dopants. The activation anneal may be performed by any technique such as RTA, flash lamp annealing (“FLA”), or laser annealing. This anneal step often causes lateral and vertical migration of dopants in the source/drain extension regions 70 and the sources/drain regions 60. In addition, this anneal step will cause the recrystallization of the ion implant areas 60, 70 (or the full crystallization of the ion implant areas 60, 70 if this is the first anneal).

As shown in FIG.2E, a blocking layer 200 is now formed over the surfaces of the exposed semiconductor substrate 30 (step 308). In the example application, the blocking layer 200 is a CoSi₂ salicide 120 (see FIG. 1) that is formed with any standard silicide process. Alternatively, the blocking layer 200 may be a different silicide layer (such as a silicide of the NiPt alloy) or a protective film such as TiN. If a protective film is used as the blocking layer then the protective film is later removed and a metal silicide layer (such as NiSi or a silicide of a Ni alloy) is formed in its place at step 320. The blocking layer 200 protects the areas of exposed semiconductor substrate 30 against silicidation during the upcoming gate silicidation process. The use of a blocking layer to protect areas of exposed silicon substrate during a gate silicidation process is described more fully in the commonly assigned patent applications having patent application Ser. No. 10/851,750 (Attorney Docket Number TI-37220, filed May 20, 2004) and patent application Ser. No. 10/810,759 (Attorney Docket Number TI-37793, filed Mar. 26, 2004), both of which are incorporated herein by reference but not admitted to be prior art with respect to the present invention by their mention in this section.

As also shown in FIG. 2E, a layer of metal 210 is now deposited over the top surface of the semiconductor wafer 10 (step 310) using any suitable deposition process such as PVD. The silicidation metal layer 210 is preferably comprised of Ni; however, other nickel alloys may be used, such as NiAl or NiPt. The optimal thickness of the silicidation metal 210 is determined by the amount of metal material that is needed to fully silicidize the gate electrode 93. Because it takes approximately 1 nm of nickel to fully silicidize approximately 1.8 nm of polysilicon, the thickness of the silicidation metal 210 should be at least 56% of the thickness of the polysilicon gate electrode 93. To be comfortable however, it is suggested that the thickness of the silicidation metal 210 should be at least 60% of the thickness of the polysilicon gate electrode 93. Thus, where the thickness of the polysilicon gate electrode 93 ranges from about 500 Å to 1300 Å in the example application, the thickness of the silicidation metal 210 should be at least 300 Å to 780 Å, respectively.

An optional cap layer 220 may also be formed over the silicidation metal layer 210 (step 312). If used, the cap layer 220 acts as a passivation layer that prevents the diffusion of oxygen from ambient into the silicidation metal layer 210. The cap layer may be any suitable material, such as TiN or Ti. In the example application, the cap layer 220 is between 50-500Å thick.

In accordance with the invention, the semiconductor wafer 10 is now annealed with a low temperature spike anneal process (step 314). Any suitable machines, such as the RadiancePlus (manufactured by Applied Materials) or the Summit (manufactured by Axcelis) may be used for the low temperature spike anneal process. In the example application, the low temperature spike anneal is performed with a peak temperature less than 550° C. and in a process ambient containing an inert gas such as N, He, or a combination of inert gases. Preferably, the time above Tₚₑₐₖ minus 50° C. is 10 seconds or less. The result of this process is an atomic ratio of reacted Ni to polysilicon of ≧1 for the gate electrode 93. This anneal process forms a nickel-rich gate silicide film (i.e. Ni₂Si) within the top 60-95% of the gate electrode 93. Moreover, the low temperature spike anneal process will cause the nickel to diffuse to a similar depth within all exposed gate electrodes 93 across the semiconductor wafer 10, regardless of whether the width of the gate electrode 93 is wide or narrow. It is to be noted that the silicidation metal layer 210 will not react with the sources/drain regions 60 and the exposed surfaces of the n-well 40 because they are protected from silicidation by the previously formed blocking layer 200.

The next step is the removal of the un-reacted portions of the silicidation metal layer 210, as shown in FIG. 2F (step 316). The metal layer 210 (and the cap layer 220, if used) is removed with any suitable process such as a selective wet etch process (i.e. using a fluid mixture of sulfuric acid, hydrogen peroxide, and water).

A silicide anneal is performed at this point in the manufacturing process in order to fully react the gate silicide (step 318). In the example application, the suicide anneal is an RTA that is performed for 10-60 seconds at a temperature between 450-600° C. This suicide anneal will compete the formation of the FUSI gate electrode 90. It is within the scope of the invention to use alternative processes for the silicide anneal, such as a spike anneal process with a peak temperature in the range of 500-650° C.

If the blocking layer 200 is a silicide layer 120, then the fabrication process continues as outlined below. However, if the blocking layer 200 is a protective film, then it is now removed and a silicide layer 120 is formed in its place, as shown in FIG. 2G (step 320). Any suitable standard process may be used to remove the protective film and from the silicide layer 120, such as those processes in the co-pending patent applications that have been incorporated by reference above.

The fabrication of the semiconductor wafer 10 now continues, using standard process steps, until the semiconductor device is complete. Generally, the next step is the formation of the dielectric insulator layer 130 using plasma-enhanced chemical vapor deposition (“PECVD”) or another suitable process (see FIG. 1). The dielectric insulator 130 may be comprised of any suitable material such as SiO₂ or OSG.

The contacts 140 are formed by etching the dielectric insulator layer 130 to expose the desired gate, source, or drain. The etched spaces are usually filled with a liner 150 to improve the electrical interface between a silicide and the contact 140. Then the contacts 140 are formed within the liner 150; creating the electrical interconnections between various semiconductor components located within the semiconductor wafer 10.

The fabrication of the final integrated circuit continues with the completion of the back-end structure described above (FIG.1). Once the fabrication process is complete, the integrated circuit will be tested and then packaged.

Various additional modifications to the invention as described above are within the scope of the claimed invention. As an example, interfacial layers may be formed between any of the layers shown. In addition, an additional anneal process may be performed after any step in the above-described fabrication process. When used, the anneal process can improve the microstructure of materials and thereby improve the quality of the semiconductor structure. Moreover, higher anneal temperatures may be used in order to accommodate transistors having thicker polysilicon gate electrodes.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method for fully siliciding a gate electrode of a transistor on a semiconductor wafer, comprising:
forming a metal layer over said semiconductor wafer;
forming a cap layer over said metal layer;
performing a low temperature spike anneal process;
removing said cap layer and unreacted portions of said metal layer; and
performing a silicide anneal to fully silicide said gate electrode;
wherein a source and a drain of said transistor are protected by a blocking layer.

2. The method of claim 1 wherein said metal layer comprises Ni.

3. The method of claim 1 wherein said cap layer comprises TiN.

4. The method of claim 1 wherein said low temperature spike anneal is performed with a peak temperature less than 550° C., in a process ambient of an inert gas, and with a duration of a temperature above Tₚₑₐₖ−50° C. of 10 seconds or less.

5. The method of claim 1 wherein said silicide anneal is a RTA process preformed at temperature between 450-600° C. for 10-60 seconds.

6. The method of claim 1 wherein said blocking layer comprises a silicide layer.

7. The method of claim 1 wherein said blocking layer comprises a nitride film.

8. A method for making a transistor, comprising:
providing a semiconductor substrate;
forming a gate dielectric coupled to said semiconductor substrate;
forming a gate electrode coupled to said gate dielectric;
forming extension sidewalls coupled to said gate electrode and said gate dielectric;
implanting extension regions within said semiconductor substrate;
forming spacer sidewalls coupled to said extension sidewalls;
implanting source and drain regions within said semiconductor substrate;
forming a blocking layer over said source and drain regions;
forming a metal layer over said semiconductor wafer;
performing a low temperature spike anneal;
removing unreacted portions of said metal layer; and
performing a silicide anneal to fully silicide said gate electrode.

9. The method of claim 8 further comprising the step of forming a cap layer over said metal layer prior to said step or performing a low temperature spike anneal.

10. The method of claim 8 wherein said blocking layer comprises a silicide layer.

11. The method of claim 8 wherein said blocking layer comprises a nitride film.

12. The Method of claim 11 further comprising the steps of:
removing said nitride film; and
forming a silicide layer on said source and drain regions.

13. The method of claim 8 wherein said metal layer comprises Ni.

14. The method of claim 9 wherein said cap layer comprises TiN.

15. The method of claim 8 wherein said low temperature spike anneal is performed with a peak temperature less than 550° C., in a process ambient of an inert gas, and with a duration of a temperature above Tₚₑₐₖ−50° C. of 10 seconds or less.

16. The method of claim 8 wherein said silicide anneal is a RTA process preformed at temperature between 450-600° C. for 10-60 seconds.

17. The method of claim 8 wherein said low temperature spike anneal creates an atomic ratio of reacted Ni atoms to Si atoms of ≧1 within said gate electrode.
